(19) United States
(12) Patent Application Publication
(10) Pub. No.: US 2012/0164809 A1
(43) Pub. Date: Jun. 28, 2012

(54) SEMICONDUCTOR DEVICES INCLUDING STRAINED SEMICONDUCTOR REGIONS, METHODS OF FABRICATING THE SAME, AND ELECTRONIC SYSTEMS INCLUDING THE DEVICES

(76) Inventors: Jun-Ho YOON, Suwon-si (KR); Kyoung-Sub SHIN, Seongnam-si (KR); Jin-Wook LEE, Seoul (KR); Je-Woo HAN, Hwaseong-si (KR); Hyung-Yong KIM, Cheongju-si (KR)

(21) Appl. No.: 13/298,732

(22) Filed: Nov. 17, 2011

(30) Foreign Application Priority Data
Dec. 27, 2010 (KR) 10-2010-0135572

(51) Int. Cl. H01L 21/336

(52) U.S. Cl. 438/303; 257/E21.409

(57) ABSTRACT

A method of fabricating a semiconductor device includes forming a gate pattern on a substrate, forming an amorphous silicon (a-Si) region adjacent to the gate pattern by implanting a dopant containing a Group IV or VIII element into portions of the semiconductor substrate, forming gate spacers on sidewalls of the gate pattern, forming a first cavity by etching the a-Si region and the substrate using a first etching process, forming a second cavity by etching the substrate, such that the second cavity expands a profile of the first cavity in lateral and vertical directions, and forming a strained semiconductor region in the second cavity.

### CROSS-REFERENCE TO RELATED APPLICATION

Korean Patent Application No. 10-2010-0135572, filed on Dec. 27, 2010, in the Korean Intellectual Property Office, and entitled: “Semiconductor Devices Including Strained Semiconductor Regions, methods of Fabricating the Same, and Electronic Systems Including the Devices,” is incorporated by reference herein in its entirety.

### BACKGROUND

1. Field

Embodiments of the inventive concept relate to semiconductor devices including strained semiconductor regions, methods of fabricating the same, and electronic systems including the devices.

2. Description of Related Art

Generally, various methods for forming a transistor having good performance have been studied to overcome restrictions caused by the high integration density and high speed of metal-oxide-semiconductor field effect transistors (MOSFETs). In particular, various methods for increasing electron or hole mobility have been developed to embody high-performance transistors.

To increase electron or hole mobility, a method of changing an energy band structure of a channel region by applying physical stress to the channel region has been proposed. For example, the performance of an NMOS transistor may be improved by applying tensile stress to a channel thereof, while the performance of a PMOS transistor may be improved by applying compressive stress to a channel thereof.

### SUMMARY

Embodiments of the inventive concept provide a semiconductor device including a strained semiconductor region.

Other embodiments of the inventive concept provide an electronic system including a semiconductor device with a strained semiconductor region.

Still other embodiments of the inventive concept provide various methods of fabricating a semiconductor device with a strained semiconductor region.

In accordance with an aspect of the inventive concept, a method of fabricating a semiconductor device includes forming a gate pattern on a substrate, forming an amorphous silicon (a-Si) region adjacent to the gate pattern by implanting a dopant containing a Group IV or VIII element into portions of the semiconductor substrate, forming gate spacers on sidewalls of the gate pattern, forming a first cavity by etching the a-Si region and the substrate using a first etching process, forming a second cavity by etching the substrate, such that the second cavity expands a profile of the first cavity in lateral and vertical directions, and forming a strained semiconductor region in the second cavity.

Etching the a-Si region and the substrate may include performing a chemical dry etching process using a reactive gas containing nitrogen trifluoride (NF₃) and chloride (Cl₂).

Etching the a-Si region and the substrate may be performed without applying a bias voltage.

Implanting the dopant may include implanting germanium (Ge) at a dose of about 4 E¹⁴/cm² or higher.

Implanting the dopant may include implanting silicon (Si) at a dose of about 1 E¹⁵/cm² or higher.

Forming the a-Si region may include forming a boundary of the a-Si region at a depth of about 100 Å to about 150 Å.

Forming the gate spacers may be performed at a temperature of about 600 Å or lower.

Forming the strained semiconductor region may include filling the second cavity with a semiconductor material layer using a selective epitaxial growth (SEG) process, the semiconductor material layer including a SiGe layer or a Ge layer.

The method may further include forming source and drain regions by implanting a dopant containing a Group III element into the strained semiconductor region, the source and drain regions having a junction deeper than a boundary of the strained semiconductor region.

Forming the a-Si region may include forming a first a-Si region in the substrate, such that the first a-Si region is vertically aligned with a sidewall of a first offset spacer on the gate pattern, and forming a second a-Si region in the substrate, such that the second a-Si region is vertically aligned with a sidewall of a second offset spacer on the first offset spacer, wherein etching the a-Si region includes performing an isotropic dry etching to etch the first and second a-Si regions, such that boundaries of the first and second a-Si regions are used as etch stop layers.

In accordance with another aspect of the inventive concept, a method of fabricating a semiconductor device includes forming a gate pattern on a substrate, forming first offset spacers on sidewalls of the gate pattern, forming a first amorphous silicon (a-Si) region in the substrate, such that the first a-Si region is vertically aligned with a sidewall of one of the first offset spacers, forming second offset spacers on the first offset spacers, forming a second a-Si region in the substrate, such that the second a-Si region is vertically aligned with a sidewall of one of the second offset spacers, forming gate spacers on the second offset spacers, forming a first cavity having a longitudinal section with a reverse arch shape by etching the first and second a-Si regions, and forming a second cavity having a longitudinal section with a double-sigma shape by etching the first cavity.

Forming the first and second a-Si regions may include implanting a dopant containing silicon (Si), germanium (Ge), argon (Ar), xenon (Xe), or krypton (Kr) into the substrate, such that the first and second a-Si regions have an etch selectivity of about 1.4 to about 2.4 with respect to the substrate.

Forming the first a-Si region may include forming a shallow pocket structure with a depth of about 100 Å to about 150 Å to control the width of the first cavity.

Forming the second a-Si region may include forming a thick pocket structure with a smaller width and greater depth than the first a-Si region to control the depth of the first cavity.

Etching the first and second a-Si regions may include performing an isotropic dry etching process using boundaries of the first and second a-Si regions as etch stop layers.

The method may further include forming a strained semiconductor region in the second cavity, the strained semiconductor region including a SiGe layer or Ge layer having an amorphous or polycrystalline structure.

In accordance with another aspect of the inventive concept, a method of fabricating a semiconductor device includes forming gate patterns on a crystalline semiconductor substrate, forming an a-Si region in the crystalline semiconductor substrate between adjacent gate patterns by implanting a dopant containing a Group IV or VIII element into the crystalline semiconductor substrate, forming a first cavity by etching the a-Si region and portions of the crystalline semiconductor substrate using a dry isotropic etching process, forming a second cavity by simultaneously expanding a profile of the first cavity in lateral and vertical directions, and forming a strained semiconductor region in the second cavity.

Forming the a-Si region may include transforming a portion of the crystalline semiconductor substrate into an amorphous region by the implantation, such that only physical properties of the substrate are changed.

Forming the first cavity may include using a boundary between the a-Si region and the crystalline semiconductor substrate as an etch stop layer, such that a width of the first cavity equals a width of the a-Si region.

The dry isotropic etching process may be performed under no bias conditions and include using a fluorine-based gas having a small number of fluorine atoms.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of a semiconductor device according to embodiments of the inventive concept;

FIGS. 2A through 2H illustrate cross-sectional views of stages in a method of fabricating a semiconductor device according to embodiments of the inventive concept;

FIGS. 3A through 3G illustrate cross-sectional views of stages in a method of fabricating a semiconductor device according to embodiments of the inventive concept;

FIG. 4 illustrates a graph of etch selectivity of a doped material according to embodiments of the inventive concept;

FIG. 5A illustrates a schematic diagram of etching variation when a homogeneous material region is fully etched;

FIG. 5B illustrates a schematic diagram of etching variation when a homogeneous material region is partially etched;

FIG. 5C illustrates a schematic diagram of etching variation when a heterogeneous material region is fully etched;

FIG. 6A illustrates a graph showing a relationship between etch selectivity and etching variation in a vertical direction;

FIG. 6B illustrates a graph showing a relationship between etch selectivity and etching variation in a lateral direction;

FIG. 7A illustrates a graph of a relationship between a reactive gas and etch selectivity;

FIG. 7B illustrates a graph of a relationship between a reactive gas and an etch rate;

FIG. 8A illustrates a partial cross-sectional view of etching variation when a first a-Si region according to the inventive concept is not formed;

FIG. 8B illustrates a partial cross-sectional view of etching variation when a second a-Si region according to the inventive concept is not formed; and

FIG. 9 illustrates a block diagram of a memory system including various semiconductor devices according to embodiments of the inventive concept.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of elements and regions may be exaggerated for clarity of illustration. It will also be understood that when an element, e.g., a layer, is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

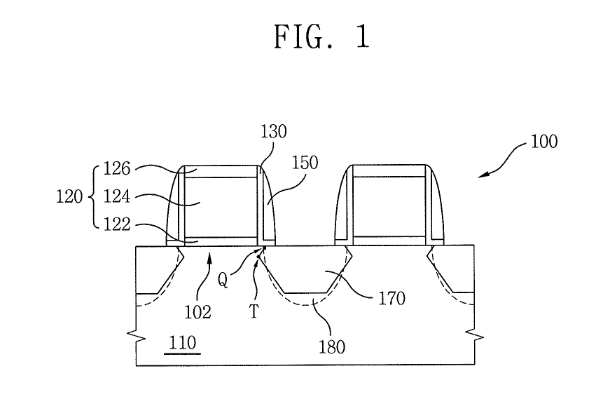

Referring to FIG. 1, a semiconductor device 100 according to the inventive concept may include a substrate 110, channel regions 102, gate patterns 120, strained semiconductor regions 170, and source and drain regions 180. Each of the gate patterns 120 may include a gate insulating layer 122, a gate electrode 124, and a gate capping layer 126, which are sequentially stacked on the substrate 110. Offset spacers 130 and gate spacers 150 may be formed on sidewalls of the gate patterns 120, i.e., on sidewalls of the gate insulating layer 122, the gate electrode 124, and the gate capping layer 126. For example, the semiconductor device 100 may be a P-type metal-oxide-semiconductor field effect transistor (PMOSFET).

The substrate 110 may include, e.g., at least one of a silicon (Si) substrate, a silicon-germanium (SiGe) substrate, a silicon-on-insulator (SOI) substrate, and a germanium-on-insulator (GOI) substrate. The channel region 102, which is a portion of the substrate 110, may be formed of the same material as the substrate 110. The substrate 110 may include a N-type dopant. The channel region 102 may be electrically insulated from the gate electrode 124 by the gate insulating layer 122.

The gate insulating layer 122 may include an insulating material having a high dielectric constant. The gate insulating layer 122 may include, e.g., at least one of silicon oxide, silicon nitride, silicon oxynitride, and an insulating metal oxide. The gate electrode 124 may include a conductive material. The gate electrode 124 may include, e.g., at least one of doped polysilicon (poly-Si), a metal, a conductive metal nitride, a conductive metal oxide, and a metal silicide. The gate capping layer 126 may include an insulating material having an etch selectivity with respect to the substrate 110 or the gate electrode 124. The gate capping layer 126 may include, e.g., at least one of silicon nitride, silicon oxide, and silicon oxynitride.

The offset spacers 130 may include an insulating material having an etch selectivity with respect to the substrate 110. The offset spacers 130 may prevent external diffusion of a dopant from the gate pattern 120, or diffusion of an external dopant into the gate pattern 120. The offset spacers 130 may be formed to a thickness of about 30 Å to about 80 Å. The offset spacers 130 may include, e.g., at least one of silicon oxide, silicon nitride, and silicon oxynitride. The gate spacers 150 may include an insulating material having an etch selectivity with respect to the substrate 110. The gate spacers 150 may include, e.g., at least one of silicon oxide, silicon nitride, and silicon oxynitride.

Each of the strained semiconductor regions 170 may be an embedded-type region adjacent the channel region 102, and may be formed to a predetermined depth as a predetermined type, in a region of the substrate 110. In other words, the strained semiconductor region 170 may be embedded within the substrate 110, e.g., an upper surface of the strained semiconductor region 170 may be substantially level with an upper surface of the substrate 110, and may be positioned between channel regions 102 of adjacent gate patterns 120. The predetermined type, e.g., shape, of the strained semiconductor regions 170 may be polygonal, e.g., a double sigma (Σ) type. The predetermined depth of the strained semiconductor regions 170 may be smaller than a depth of a junction of the source and drain regions 180, e.g., a distance from the top surface of the substrate 110 to a bottom of the strained semiconductor region 170 may be smaller than a distance from the top surface of the substrate 110 to a bottom of the source and drain region 180. The junction of the source and drain regions 180 may surround the strained semiconductor region 170, e.g., at least a portion of the source drain region 180 may be between the top surface of the substrate 110 and the bottom of the strained semiconductor region 170. When the substrate 110 includes a silicon substrate, the strained semiconductor region 170 may include a SiGe layer and/or a Ge layer having a greater crystal lattice and bonding length than the silicon substrate, i.e., than Si.

In detail, when the strained semiconductor region 170 formed adjacent to the channel region 102 of the PMOSFET includes SiGe or Ge, the SiGe or Ge may have the same lattice structure as the Si forming the substrate 110 but a greater lattice constant than the Si. Accordingly, since the SiGe or Ge forming the strained semiconductor region 170 has a greater lattice constant, i.e., atomic value, than the Si forming the channel region 102, compressive stress may be applied to the channel region 102 of the PMOSFET, and the effective mass and hole mobility of the channel region 102 may be increased. When the strained semiconductor region 170 includes Ge, the percentage of Ge may be about 100%, e.g., the strained semiconductor region 170 may consist essentially of Ge. However, when the strained semiconductor region 170 includes SiGe, the percentage of Ge may be at least 5%, e.g., at least 5% of the content of the strained semiconductor region 170 may be Ge, thereby enabling application of compressive stress to the channel region 102.

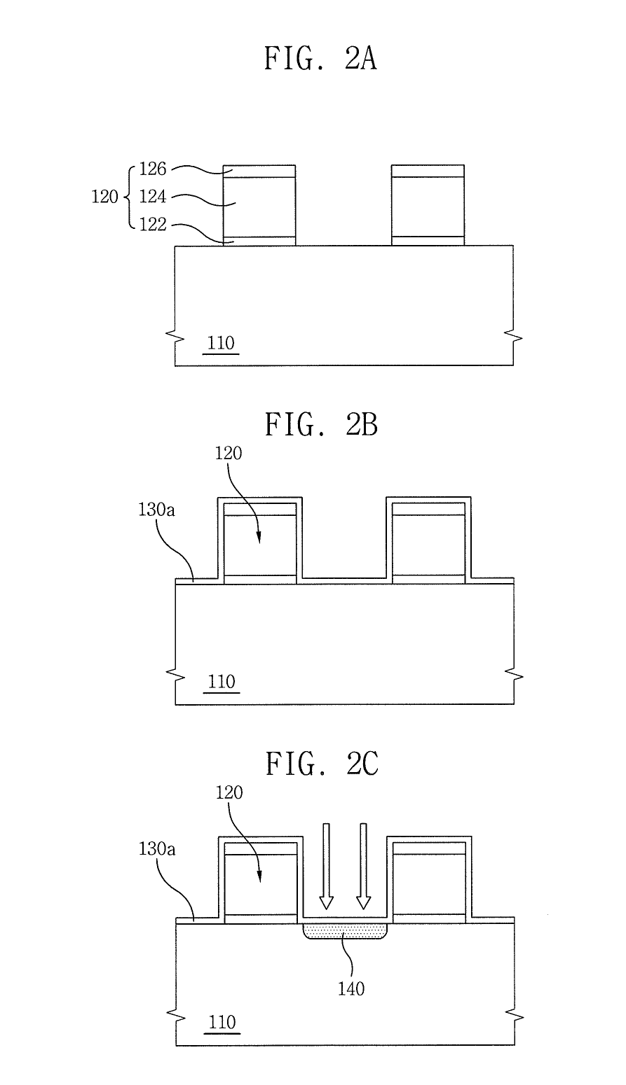

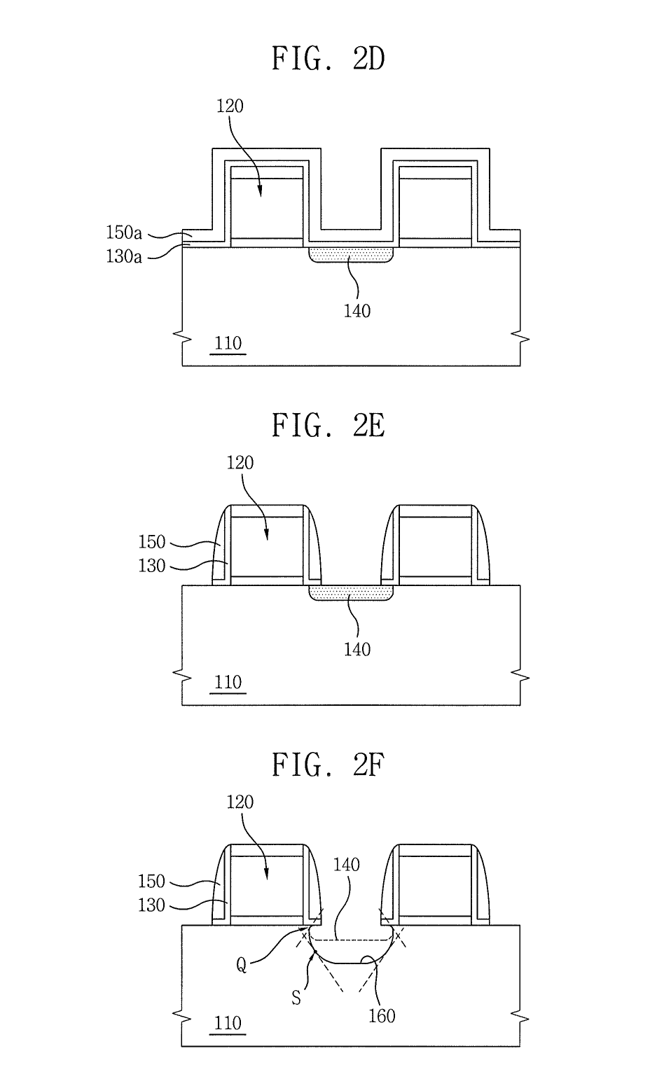

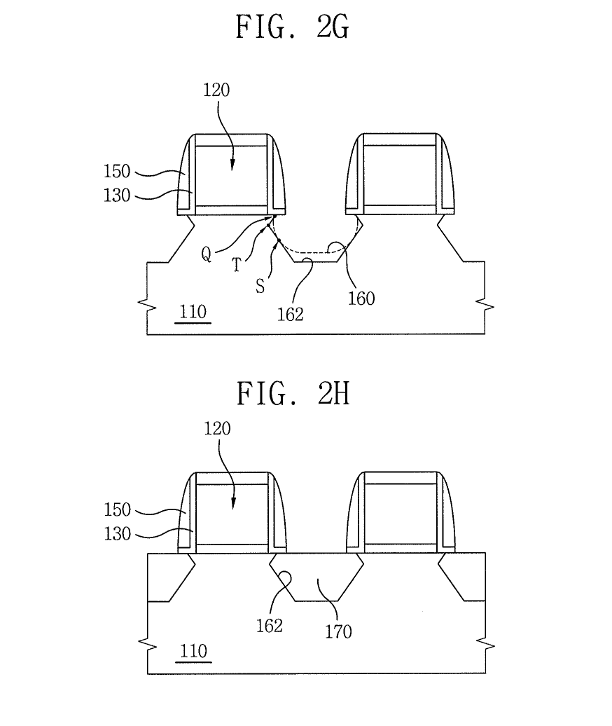

The strained semiconductor region 170 may include a tip T protruding in the lateral direction toward an adjacent channel region 102 in the sigma-type strained semiconductor region 170. That is, the polygonal shape of the strained semiconductor region 170 may include a vertex, i.e. the tip T, that extends toward an adjacent channel region 102. The tip T may be adjusted so the proximity between the tip T and the gate pattern 120 is the highest, since a position of the tip T may directly affect the hole mobility of the channel region 102, as will be discussed in more detail below with reference to FIG. 2G. Also, the strained semiconductor region 170 may generally have a regular profile, e.g., symmetric. When a strained semiconductor region has an irregular profile, the extent of application of compressive stress to an adjacent channel region 102 may vary, thereby causing irregular hole mobility in the channel region 102.

The strained semiconductor region 170 may include a first etch stop point Q vertically aligned with an outer sidewall of the offset spacer 130. The position of the first etch stop point Q may vary according to the thickness of the offset spacer 130. Also, the position of the tip T may vary according to the position of the first etch stop point Q. For example, as the position of the first etch stop point Q gets farther away from the channel region 102 in the lateral direction, the position of the tip T may also get farther away from the channel region 102. Accordingly, by adjusting the thickness of the offset spacer 130, the position of the tip T may be controlled, thereby also controlling the proximity between the gate pattern 120 and the tip T.

The source and drain regions 180 may be in contact with a contact structure (not shown). The source and drain regions 180 may be formed by implanting a P-type dopant into the strained semiconductor regions 170. A junction of the source and drain regions 180 may be formed to a greater depth than a boundary of the strained semiconductor region 170.

Hereinafter, a method of fabricating a semiconductor device having the above-described structure according to the inventive concept will be described in detail with reference to the accompanying drawings.

### Embodiment 1

FIGS. 2A through 2H are cross-sectional views of stages in a method of fabricating a semiconductor device according to the inventive concept.

Referring to FIG. 2A, the gate patterns 120 may be formed on the substrate 110. A first insulating layer, a conductive layer, and a second insulating layer may be sequentially deposited on the entire surface of the substrate 110 and patterned, thereby forming a plurality of gate insulating layers 122, a plurality of gate electrodes 124, and a plurality of gate capping layers 126. The substrate 110 may include a single crystalline silicon substrate. The first insulating layer may include a silicon oxide layer, a silicon nitride layer, a silicon oxynitride layer, and/or an insulating metal oxide layer. The first insulating layer may be formed, e.g., using an oxidation process or an oxide deposition process. The conductive layer may include a doped poly-Si layer, a metal layer, a conductive metal nitride layer, a conductive metal oxide layer, a metal silicide layer, and/or a stacked layer thereof. The conductive layer may be formed, e.g., using a deposition process. Alternatively, an ion implantation process of doping a P-type dopant into the conductive layer may be further performed. The second insulating layer may include a silicon nitride layer, a silicon oxide layer, and/or a silicon oxynitride layer. The second insulating layer may be formed, e.g., using a deposition process. The second insulating layer may be used as an etch mask for the conductive layer. For example, the gate capping layer 126 may be formed using a photolithography process, and the conductive layer may be etched using the gate capping layer 126 as an etch mask, thereby forming the gate electrode 124 and the gate insulating layer 122. Also, the second insulating layer may prevent an upper portion of the gate electrode 124 from being damaged during a subsequent etching process. Due to the above-described patterning process, the gate insulating layer 122, the gate electrode 124, and the gate capping layer 126 may form the gate pattern 120.

Referring to FIG. 2B, an offset spacer insulating layer 130a may be formed on the entire surface of the substrate 110. The offset spacer insulating layer 130a may be continuously formed along profiles of the substrate 110 and the gate patterns 120, e.g., using a deposition process. The offset spacer insulating layer 130a may be conformally deposited to a thickness of about 30 Å to about 80 Å. The offset spacer insulating layer 130a may include a silicon oxide layer and/or a silicon nitride layer.

Referring to FIG. 2C, an ion implantation process (IIP) of implanting a dopant into the substrate 110 may be performed to change the physical properties of the substrate 110, e.g., to change a portion of a crystalline structure of the substrate 110 into an amorphous structure. In detail, by implanting a dopant containing a Group IV or VIII element at a critical dose into the substrate 110, only the physical properties of the substrate 110 may vary without changing the electrical properties of the substrate 110. For example, a dopant containing a Group IV element, e.g., a Si dopant at an implantation dose of at least 1 E¹⁵/cm² or a Ge dopant at an implantation dose of at least 4 E14/cm², may be implanted into the substrate 110. In another example, an ion implantation process may be performed using a dopant containing a Group VIII element, e.g., an Ar dopant, a Xe dopant, or a Kr dopant. As described above, when the dopant of Group IV or VIII element is doped into the substrate 110 at a critical dose or higher, the crystallinity of the substrate 110 may be transformed from c-Si into a-Si. Therefore, the ion implantation process may form amorphous doped regions, i.e., a-Si regions 140, between crystalline portions of the substrate 110, i.e., between channel regions 102. It is noted that the doping process described with reference to FIG. 2C should not be followed by a diffusion process for activating the dopant, as will be described in more detail with reference to FIG. 4.

The a-Si regions 140 may be formed in an upper portion of the substrate 110, e.g., the a-Si regions 140 may be between the substrate 110 and the offset spacer insulating layer 130a, and may be positioned between adjacent gate patterns 120. The a-Si regions 140 may exhibit higher etch selectivity than other portions of the substrate 110, as will be explained in more detail below with reference to FIG. 4.

FIG. 4 is a graph showing etch selectivities of doped materials. Referring to FIG. 4, when Si or Ge dopant is implanted into a material, etch selectivity of a doped material region with respect to an undoped material region may be increased. For example, as illustrated in FIG. 4, etch selectivity of doped portions of material may increase from 1.0 to 1.4 and 1.6 (refer to reference symbols and ◯ indicating etch selectivities). Therefore, doped portions of the substrate 110, e.g., a-Si regions 140, may exhibit higher etch selectivity than undoped portions of the substrate 110, i.e., crystalline portions of the substrate 110, after Si or Ge doping.

Further, a rapid temperature annealing (RTA) process for diffusing the dopant may not be performed. For example, when a RTA process is performed at a temperature of about 600° C. or higher, the a-Si region may be re-crystallized and converted into a c-Si region, thereby reducing etch selectivity (indicated by the arrow in FIG. 4; also refer to reference symbols ★ and ⋆ indicating etch selectivities measured after the RTA process). Accordingly, after the dopant is implanted into the substrate 110, a diffusion process, e.g., including the RTA process, for activating the dopant may be omitted.

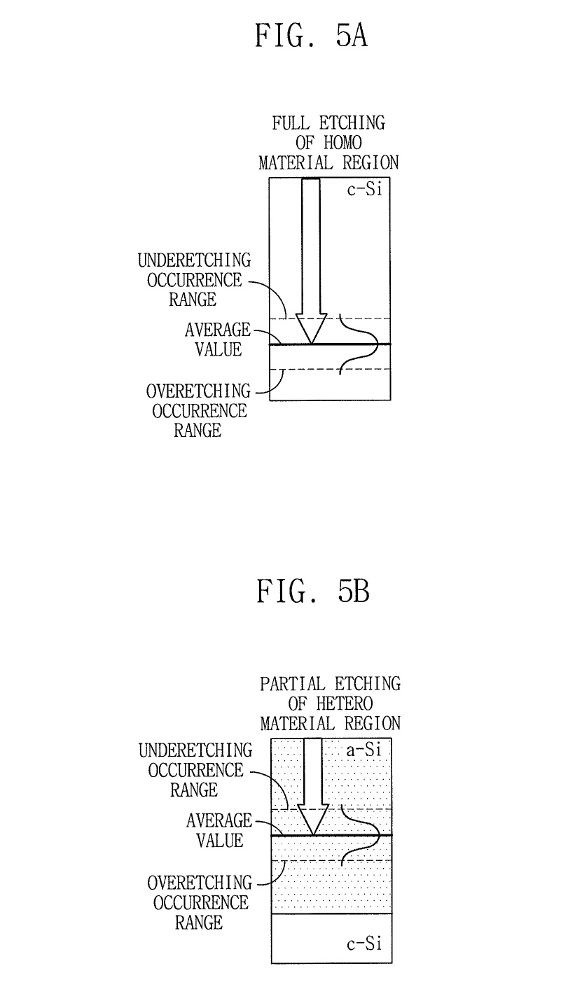

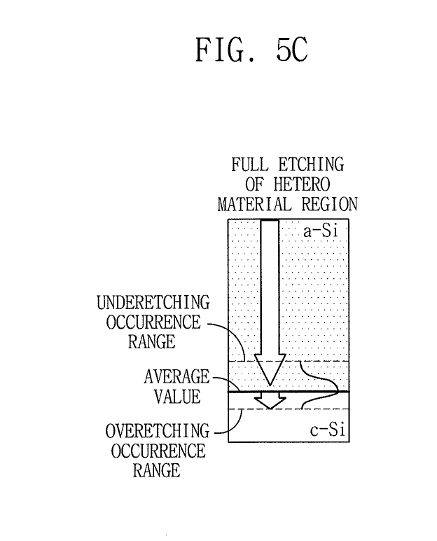

Referring back to FIG. 2C, the a-Si regions 140 may extend horizontally between extension lines of facing outer surfaces of portions of offset spacer insulating layer 130a corresponding to adjacent gate patterns 120. That is, a vertical boundary line between the a-Si region 140 and the substrate 110 may be coextensive, e.g., may overlap, an imaginary extension line of a vertical portion of an outer surface of the offset spacer insulating layer 130a. The boundary line between the substrate 110 and the a-Si region 140 may function as an etch stop layer, as will be discussed in more detail with reference to FIGS. 5A-5C, during a subsequent recess process.

FIG. 5A is a schematic diagram of etching variation within a homogenous material region that is fully etched, FIG. 5B is a schematic diagram of etching variation within a heterogeneous material region that is partially etched, and FIG. 5C is a schematic diagram of etching variation within a heterogeneous material that is fully etched.

For instance, when a homogenous material region is fully etched, i.e., as shown in FIG. 5A, or when a heterogeneous material region is partially etched (within a single type material), i.e., as shown in FIG. 5B, etching variation, i.e., range of overetching and underetching, may be large. In contrast, as illustrated in FIG. 5C, when a heterogeneous material region is fully etched, the etching variation is smaller than in FIGS. 5A and 5B.

In detail, the homogenous material region may include only an undoped material (or c-Si) region or only a doped (or a-Si) region, while the heterogeneous material may include both doped and undoped material, e.g., a doped material (or a-Si) in an upper (or inner) portion thereof and an undoped material (or c-Si) in a lower (or outer) portion thereof. It is noted that the substrate 110 may be interpreted as the undoped material (or c-Si) region, while the a-Si region 140 may be interpreted as the doped material (or a-Si) region.

For example, when only the homogeneous material region is recessed, as shown in FIGS. 5A and 5B, an occurrence range of underetching may coincide with that of overetching on the basis of an average value, irrespective of the doped material (or a-Si) region or the undoped material (or c-Si) region. However, as shown in FIG. 5C, since the doped material (or a-Si) region disposed in the upper (or inner) portion thereof is etched at a higher etch rate than the undoped material (or c-Si) region disposed in the lower (or outer) portion thereof, when the heterogeneous material region having different etch selectivities is recessed, the occurrence range of overetching may be smaller than that of underetching on the basis of an average value. Accordingly, when the heterogeneous material region is recessed, the probability that overetching will occur may be smaller, as compared to etching of a homogeneous material region. Thus, a boundary of the heterogeneous material region may be used as an etch stop layer during the recess process, so etching variation therein, i.e., as shown in FIG. 5C, may be smaller than etching variation in a partially etched homogeneous material, as shown in FIG. 5B.

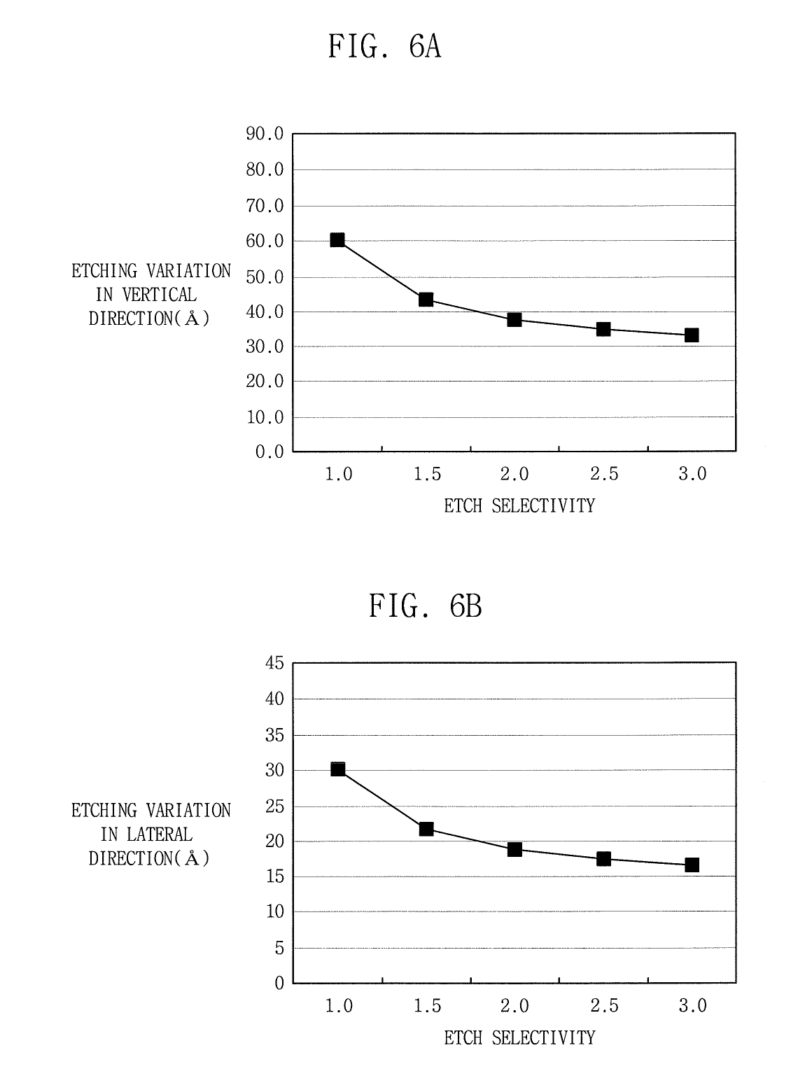

FIG. 6A is a graph showing the relationship between etch selectivity and etching variation in a vertical direction, and FIG. 6B is a graph showing the relationship between etch selectivity and etching variation in a lateral direction. Referring to FIGS. 6A and 6B, as etch selectivity increases, etching variation may decrease, and the profile uniformity of the first cavity (refer to 160 in FIG. 2F) may be improved during a subsequent etching process. For example, as illustrated in FIGS. 6A-6B, when etching selectivity is increased, e.g., changed from 1.0 to 2.0, etching variation measured in the vertical direction may be reduced by about 2 nm, i.e., from 60 Å to 37 Å, and etching variation measured in the lateral direction may be reduced by about 1 nm, i.e., from 30 Å to 18 Å.

Referring back to FIG. 2C, as the a-Si regions 140 are formed to have a high etching selectivity with respect to other portions of the substrate 110, the size of the a-Si regions 140, i.e., depth and width, may be controlled to provide a desired size/shape of a boundary between the s-Si regions 140 and the other portions of the substrate 110 for functioning as an etch stop. A shallow ion implantation process using low ion implantation energy may be performed so that the depth of the a-Si region 140, i.e., along the vertical direction, may not exceed about 150 Å and the width of the a-Si region 140 may correspond to a distance between facing offset spacers 130 of adjacent gate patterns 120. Accordingly, the first a-Si region 140 may have a shallow pocket structure.

In detail, due to the ion implantation process IIP, since a dopant may be ionized, accelerated at a high kinetic energy, and forcibly implanted into the surface of the substrate 110, the implanted projection range, i.e., depth, or extent of ions, i.e., width, may vary according to the amount of the dopant and/or the magnitude of the ion implantation energy. That is, by adjusting an acceleration voltage, an ion implantation peak may be finely changed, and the projection range, i.e., the depth, within which the dopant is implanted may be freely controlled. For example, the depth of the a-Si region 140 may be precisely controlled to be between 100 Å and 150 Å. Also, the a-Si region 140 may be vertically aligned with an outer sidewall of the offset spacer insulating layer 130a. Accordingly, the width of the a-Si region 140 along the horizontal direction may be determined according to the thickness of the offset spacer insulating layer 130a, i.e., along the horizontal direction. Therefore, according to the inventive concept, the depth and width of the a-Si region 140 may be precisely controlled by implanting ions so that the a-Si region 140 may act as an etch stop layer during a subsequent etching process. Accordingly, etching variation may be improved and the profile of the first cavity (refer to 160 in FIG. 2F) may become constant.

Referring to FIG. 2D, a gate spacer insulating layer 150a may be formed on the offset spacer insulating layer 130a. The gate spacer insulating layer 150a may include a silicon oxide layer, a silicon nitride layer, and/or a silicon oxynitride layer. The gate spacer insulating layer 150a may be formed, e.g., using a deposition process.

Referring to FIG. 2E, offset spacers 130 and gate spacers 150 may be formed on sidewalls of the gate pattern 120. The offset spacers 130 and the gate spacers 150 may be formed, e.g., using a dry or wet etching process. For example, the gate spacer insulating layer 150a may be deposited and etched at a low temperature, e.g., lower than 600° C. As described above, when the deposition or etching process is performed at a temperature higher than 600° C., a-Si may be re-crystallized, via RTA, and restored to single crystalline silicon (c-Si) state, thereby reducing etch selectivity.

Referring to FIG. 2F, a first recess process may be performed to form a first cavity 160 in the substrate 110. The first recess process may be a chemical dry etching process performed in the vertical and lateral directions to remove the a-Si region 140 and a portion of the substrate 110, such that the cavity 160 may be formed in the substrate 110. In this case, an etch gas may include a fluorine (F)-based gas having a small number of F atoms, e.g., a fluorine gas having less than four F atoms. For example, the etch gas may be a nitrogen trifluoride (NF₃) gas and/or a Cl₂ reactive gas and a He inert gas. The chemical dry etching process may be an isotropic dry etching process performed under low-energy conditions without applying a back bias voltage to simultaneously perform the recess process in vertical and lateral directions of the substrate 110.

For example, during the isotropic dry etching process, although etching may be initially performed only in the vertical direction of the substrate 110 due to the gate spacers 150, etching may be subsequently performed both in the vertical and lateral directions of the substrate 110 while exposing lateral surfaces of the substrate 110. As a result, undercuts may be formed under the gate spacers 150. The extent of the undercuts may depend on the width of the a-Si region 140 or a horizontal thickness of the gate spacers 150. Due to the isotropic dry etching process, since a ratio of a vertical etch rate to a lateral etch rate is about 2:1, an exposed center portion of the a-Si region 140 may have a higher Si etch rate than an unexposed edge portion thereof. Therefore, a center portion of a resultant cavity 160 may have a greater depth than the edge portion thereof, i.e., an amount of the substrate 110 removed during etching may be larger along the vertical direction than along the lateral direction. Accordingly, the first cavity 160 may have a cross-sectional structure with a reverse arch or vessel shape, e.g., a wide semi-elliptical shape. However, even if the width of the first cavity 160 is expanded due to the undercut, i.e., below the gate spacers 150, the first etch stop point Q, i.e., a point corresponding to a top edge of the pocket structure at the boundary of the a-Si region 140, may function as an etch stop layer so that the width of the first cavity 160 may be equal to that of the a-Si region 140. That is, the boundary between the etch selectivity a-Si region 140 and the substrate 110 may act as an etch stop layer in the horizontal direction, so when the a-Si region 140 is removed by the etching, a width of the resultant cavity 160 may equal a width of the a-Si region 140.

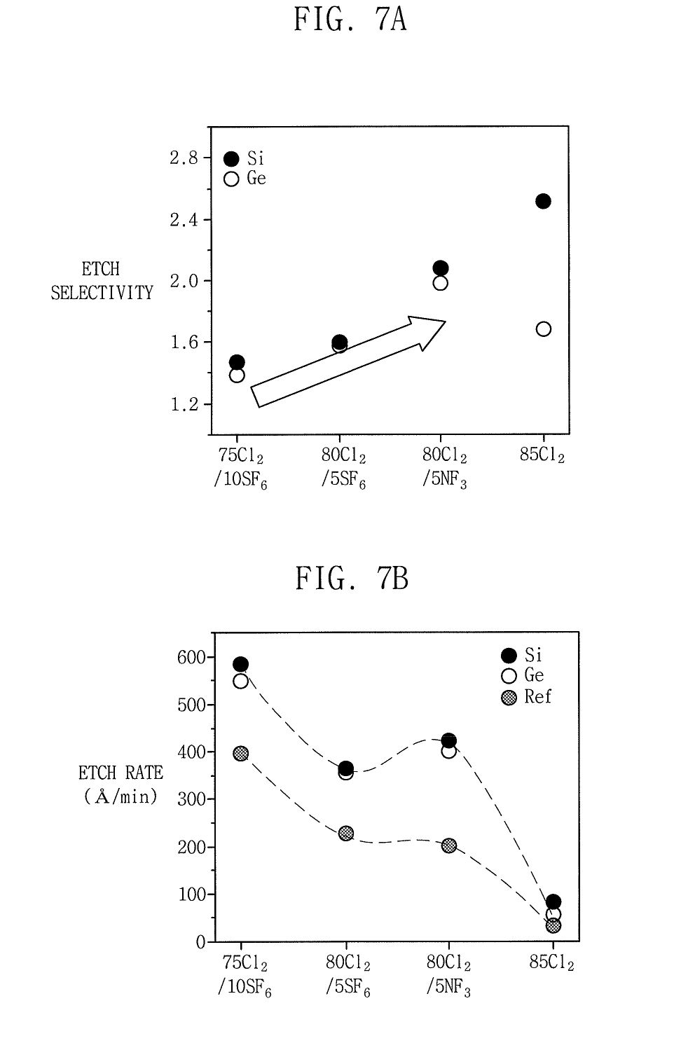

FIG. 7A is a graph showing the relationship between a reactive gas and etch selectivity, and FIG. 7B is a graph showing the relationship between a reactive gas and an etch rate. Referring to FIG. 7A, when the number of F atoms is reduced by changing a reactive gas from SF₆ into NF₃, etch selectivity may be increased. Referring to FIG. 7B, when the reactive gas is changed from sulfur hexafluoride (SF₆) into NF₃, an etch rate of c-Si may be reduced, while an etch rate of a-Si may be increased. Accordingly, etch selectivity may increase under low-fluorine conditions. For example, when the reactive gas is changed from SF₆ into NF₃, etch selectivity may be increased from 1.4 to 2.0 in both cases where Si and Ge dopants are used. In particular, when a-Si is formed using the Si dopant, etch selectivity of a-Si may be increased to 2.4. Meanwhile, even if only Cl₂ gas is used as the reactive gas, etch selectivity of a-Si may be increased. However, when only the Cl₂ reactive gas is used, an etch rate may become lower than when both Cl₂ gas and NF₃ gas are used, thereby reducing processing speed.

Referring back to FIG. 2F, the first recess process may include a blanket etch process using the gate patterns 120 and the gate spacers 150 as an etch mask. Also, although the first recess process is a partial etching process for partially removing the substrate 110, the first recess process may be a full etch process using the boundary of the a-Si regions 140 as an etch mask. The first recess process may be performed in-situ or ex-situ along with the etching of the gate spacer insulating layer 150a. For example, when the first recess process is performed in-situ, the etching of the gate spacer insulating layer 150a and the dry etching process may be continuously performed in the same process chamber. When the first recess process is performed ex-situ, the etching of the gate spacer insulating layer 150a and the dry etching process may be discontinuously performed in separate process chambers.

Referring to FIG. 2G, a second recess process may be performed to form a second cavity 162. The second recess process may include a wet etching process. The wet etching process may be performed using a solution mixture of ammonium hydroxide (NH₄OH), hydrogen peroxide (H₂O₂), and pure water (H₂O). Due to the wet etching process, the first cavity 160, i.e., a cavity having a curved cross-sectional structure with a reverse arch shape, may be converted into a second cavity 162, i.e., a cavity having a longitudinal sectional structure with a double sigma shape. During the wet etching process, Si or SiGe may be removed in the vertical and lateral directions, i.e., without removing Si or SiGe in a diagonal direction. That is, etching may be performed in directions of crystal planes <110> and <001> of the first cavity 160 but not in a direction of a crystal plane <111> of the first cavity 160. Accordingly, the etching process may not be performed at a second etch stop point S, i.e., a tangent line at point S makes an angle of about 54.74° with the surface of the substrate 110. By performing the etching process to the tip T, i.e., where a tangent line to the first etch stop point Q intersects the tangent line to the second etch stop point S at a right angle, the second cavity 162 may have a longitudinal sectional structure with a double sigma (Σ) shape. Since the tip T protrudes in the lateral direction, the proximity between the tip T and the gate pattern 120 may be the highest. Accordingly, the protruding extent of the tip T may most greatly affect hole mobility. A PMOS transistor may maintain constant performance when the proximity of the tip T does not vary, e.g., the variation thereof is uniform. When variations of the first and second etch stop points Q and S are reduced, the variation of the tip T determined by the first and second etch stop points Q and S may be also reduced, and the performance of the PMOS transistor may be improved.

Referring to FIG. 2H, a strained semiconductor region 170 may be formed to fill the second cavity 162. The strained semiconductor region 170 may include an undoped semiconductor pattern. The strained semiconductor region 170 may have an amorphous structure or a polycrystalline structure. For example, the formation of the strained semiconductor region 170 may include depositing an amorphous or polycrystalline semiconductor material layer using a chemical vapor deposition (CVD) process to fill the second cavity 162, and partially etching back the semiconductor material layer to leave the semiconductor material layer in the second cavity 162. Here, the semiconductor material layer may include a SiGe or Ge layer. In another case, the strained semiconductor region 170 may have a single crystalline structure. For example, the strained semiconductor region 170 may include a semiconductor material layer, such as a SiGe or Ge layer, which may be grown using a selective epitaxial growth (SEG) process from the second cavity 162, and fill the second cavity 162. The SEG process may include a CVD process, a reduced pressure CVD (RPCVD) process, or an ultrahigh vacuum CVD process. A SiGe layer may be selectively epitaxially grown only in a Si region exposed by the epitaxial growth process, thereby forming the strained semiconductor region 170. The SiGe layer may have a strained structure due to a difference in lattice constant between Ge and Si. During the epitaxial growth process, Si₂H₆, SiH₄, SiH₂Cl₂, SiHCl₃, or SiCl₄ may be used as a Si source gas, and GeH₄ may be used as a Ge source gas. Also, the Si source gas and the Ge source gas may be used together as a SiGe source gas. In addition, HCl or Cl₂ may be used as an etch gas to prevent the gate spacers 150 from being epitaxially grown.

When the second cavity 162 is filled with a semiconductor material layer, such as a SiGe or Ge layer as described above, compressive stress may be generated in the lateral direction of the substrate 110, and a layer to which the compressive stress is applied may be formed in the channel region (refer to 102 in FIG. 1). By increasing the effective mass of the channel region 102, the hole mobility of the channel region 102 may also be increased. For example, since the SiGe layer epitaxially grown on the substrate 110 has a higher lattice constant and greater bonding length than a Si layer, the SiGe layer may tend to extend in the lateral direction of the substrate 110. The channel region 102 may receive compressive stress between SiGe layers. Thus, Si forming the channel region 102, which may receive the compressive stress due to the SiGe layer, may have higher hole mobility than typical Si, thereby improving the speed of the semiconductor device. Also, when Si forming the second cavity 162 has a constant profile, growth speed of the SiGe layer may be maintained constant along the entire Si profile during the epitaxial growth of the SiGe layer, thereby preventing or suppressing loading effects. When Si forming a cavity has an irregular profile, the growth speed of the SiGe layer may vary according to each profile, and loading effects may occur.

Referring to FIG. 1, a dopant may be implanted into the undoped strained semiconductor region 170, thereby forming source and drain regions 180. Specifically, the dopant may be implanted into the strained semiconductor region 170, and may be activated to form the source and drain regions 180. A junction of the source and drain regions 180 may be formed to a greater depth than the strained semiconductor region 170. Accordingly, the source and drain regions 180 may surround the strained semiconductor region 170. In this case, a P-type dopant may be implanted into an N-type substrate 110 using the gate spacers 150 as an ion implantation mask. The P-type dopant may include boron (B). The implantation of the dopant may be performed in-situ.

### Embodiment 2

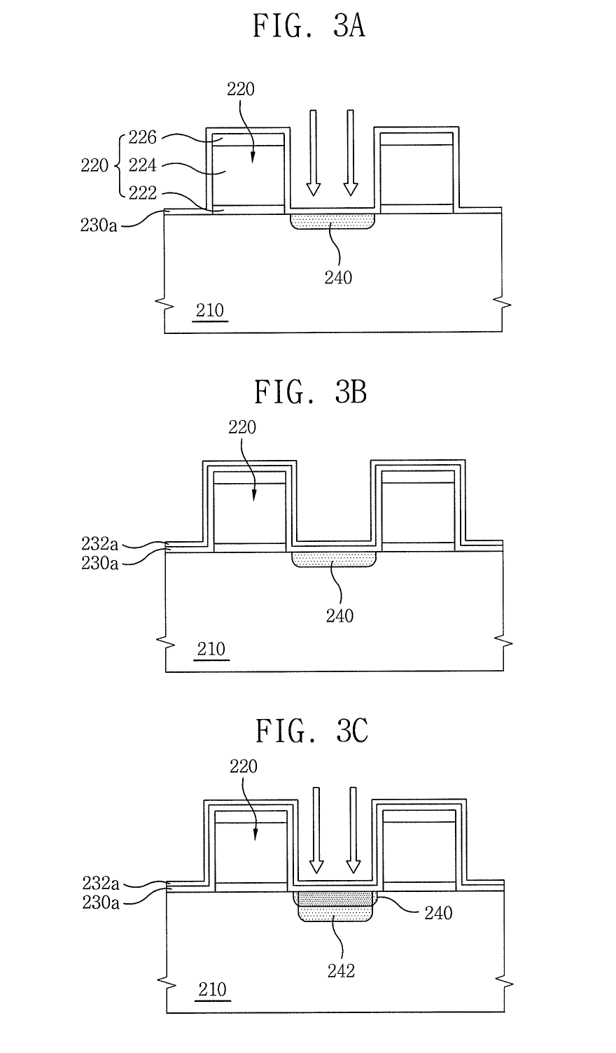

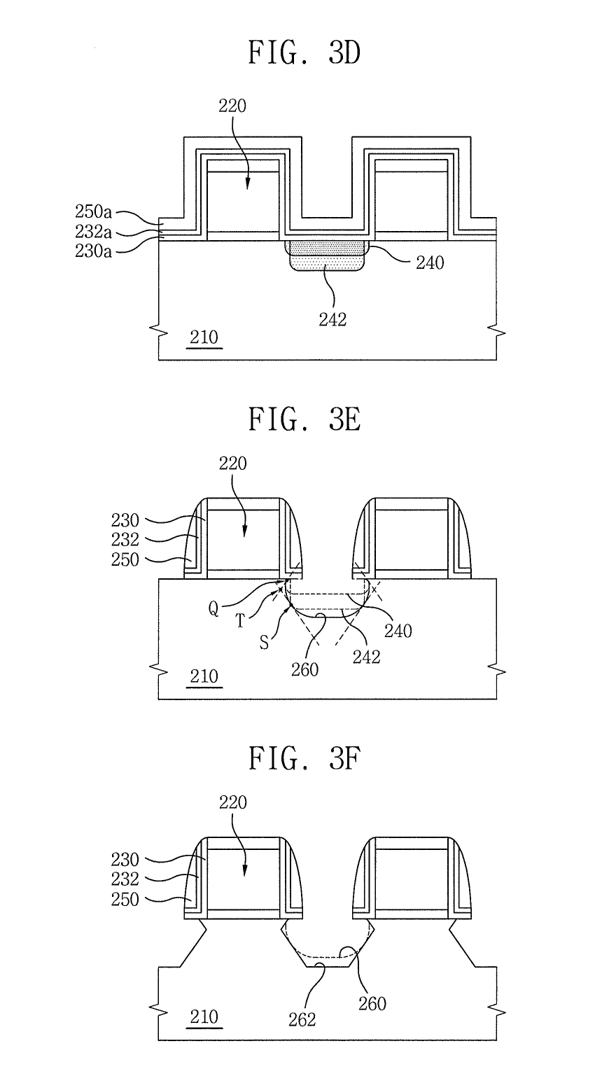

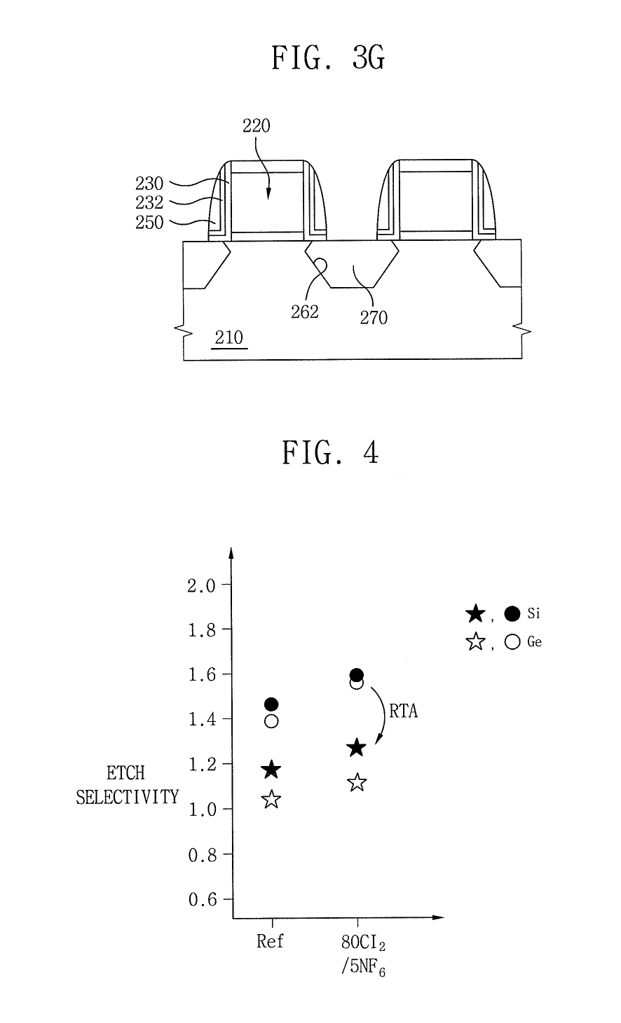

FIGS. 3A through 3G are longitudinal sectional views showing a method of fabricating a semiconductor device according to embodiments of the inventive concept.

Referring to FIG. 3A, a gate pattern 220 may be formed on a substrate 210. The gate pattern 220 may include a gate insulating layer 222, a gate electrode 224, and a gate capping layer 226 sequentially stacked on the substrate 210. A first offset spacer insulating layer 230a may be formed on the entire surface of the substrate 210 using a deposition process. The first offset spacer insulating layer 230a may be conformally deposited to a thickness of about 30 Å to about 80 Å along profiles of the substrate 10 and the gate pattern 220. A first ion implantation process IIP of implanting a dopant containing a Group IV element, e.g., Si or Ge, or a dopant containing a Group VIII element, e.g., Ar, Xe, or Kr, into the substrate 210 may be performed, thereby forming an a-Si region 240. The first offset spacer insulating layer 230a may include, e.g., a silicon oxide layer or a silicon nitride layer.

Referring to FIG. 3B, a second offset spacer insulating layer 232a may be formed on the entire surface of the substrate 210 using a deposition process. The second offset spacer insulating layer 232a may be conformally deposited on the first offset spacer insulating layer 230a to a thickness of about 30 Å to about 80 Å along the profiles of the substrate 210 and the gate pattern 220. The second offset spacer insulating layer 232a may include the same material as the first offset spacer insulating layer 230a.

Referring to FIG. 3C, a second ion implantation process IIP of implanting a dopant into the substrate 210 may be performed to change the physical properties of the substrate 210. Similarly, a dopant containing a Group IV element, e.g., Si or Ge, or a dopant containing a Group VIII element, e.g., Ar, Xe, or Kr, may be implanted into the substrate 210, thereby changing only the physical properties of the substrate 210 and not the electrical properties of the substrate 210. Due to the second ion implantation process IIP by which the crystallinity of the substrate 210 is switched from single crystalline silicon (c-Si) to amorphous silicon (a-Si), a second a-Si region 242 may be formed. The first a-Si region 240 may be formed to have a shallow pocket structure with a depth of about 100 Å to about 150 Å, and the second a-Si region 242 may be formed to have a thick pocket structure with a smaller width and greater depth than the first a-Si region 240.

Referring to FIG. 3D, a gate spacer insulating layer 250a may be formed on the second offset spacer insulating layer 232a using a deposition process. The gate spacer insulating layer 250a may include, e.g., a silicon oxide layer, a silicon nitride layer, or a silicon oxynitride layer.

Referring to FIG. 3E, first offset spacers 230, second offset spacers 232, and gate spacers 250 may be formed on sidewalls of the gate pattern 220 using a dry or wet etching process. A first recess process using the gate spacers 250 as an etch mask may be performed, thereby forming a first cavity 260. The first recess process may be a chemical dry etching process using nitrogen trifluoride (NF₃) and/or chloride (Cl₂) as a reactive gas. The first recess process may be an isotropic dry etching process performed without applying a back bias voltage. Due to the isotropic dry etching process, since the ratio of a vertical etch rate to a lateral etch rate is about 2:1, an exposed center portion of the second a-Si region 242 may have a higher Si etch rate than an unexposed edge portion thereof, so that the center portion of the second a-Si portion 242 may have a greater depth than the edge portion thereof. Accordingly, the first cavity 260 may have a longitudinal sectional structure with a reverse arch or vessel shape. Even if the width of the first cavity 260 is expanded due to the undercut, a first etch stop point Q, which may correspond to a top edge of the pocket structure at the boundary of the first a-Si region 240, may function as an etch stop layer so that the width of the first cavity 260 may be substantially equal to that of the first a-Si region 240. Also, since a second etch stop point S which may correspond to a bottom end of the pocket structure at the boundary of the second a-Si region 242, functions as an etch stop layer, the depth of the first cavity 260 may be controlled by the second a-Si region 242. In particular, the depth of the first cavity 260 may be substantially equal to that of the second a-Si region 242 in a portion vertically aligned with a sidewall of the second offset spacer 232. The first a-Si region 240 may control the width of the first cavity 260, while the second a-Si region 242 may control the depth of the first cavity 260.

Referring to FIG. 3F, a second recess process for expanding the first cavity 260 may be performed to form a second cavity 262. The second recess process may include a wet etching process. Due to the wet etching process, the first cavity 260 having a longitudinal sectional structure with the reverse arch shape may be converted into the second cavity 262 having a longitudinal sectional structure with a double sigma shape. Due to the wet etching process, while an etching process may be performed in the directions of the crystal planes <110> and <001> of the first cavity 260, the etching process cannot be performed in a direction of the crystal plane <111>. Accordingly, the etching process may not be performed at a second etch stop point S to which a tangent line makes an angle of about 54.74° with the surface of the substrate 210. By performing the etching process to the tip T at which a tangent line to the first etch stop point Q intersects a tangent line to the second etch stop point S at a right angle, the second cavity 262 may have a longitudinal sectional structure with a double sigma shape. Since the tip T protrudes, proximity between the tip T and the gate pattern 220 may be the highest, and the protruding extent of the tip T may most greatly affect hole mobility. Any PMOS transistor may maintain constant performance when the proximity of the tip T does not vary. When variations of the first and second etch stop points Q and S are reduced, the variation of the tip T determined by the first and second etch stop points Q and S may also be reduced.

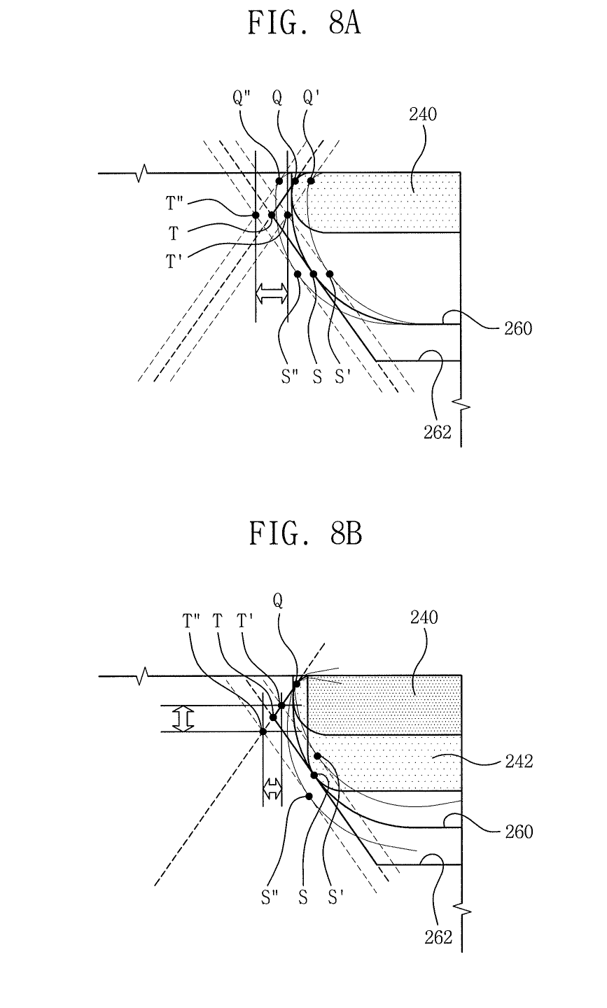

FIG. 8A is a partial longitudinal sectional view showing etching variation when the first a-Si region according to the inventive concept is not formed, and FIG. 8B is a partial longitudinal sectional view showing etching variation when the second a-Si region according to the inventive concept is not formed. Referring to FIG. 8A, when the first a-Si region 240 is not formed, the first etch stop point Q may be shifted to a point Q′ or Q″ in the lateral direction. In this state, when first and second recess processes are performed, the variation of the tip T may increase (refer to T, T′, and T″). In particular, the variation of the tip T may increase in the lateral direction. Referring to FIG. 8B, when the a-Si region 242 is not formed, the second etch stop point S may be shifted to a point S′ or S″ in the lateral and vertical directions. In this state, when the first and second recess processes are performed, the variation of the tip T may increase (refer to T, T′ and T″). In particular, the variation of the tip T may increase in both the lateral and vertical directions.

Referring to FIG. 3G, the second cavity 262 may be filled with a SiGe or Ge layer, thereby forming a strained semiconductor region 270. The strained semiconductor region 270 may have an amorphous or polycrystalline structure, or an epitaxially grown single-crystalline structure. When the second cavity 262 is filled with the SiGe or Ge layer, compressive stress may be generated in the lateral direction of the substrate 210, and hole mobility may increase.

### Applied Example

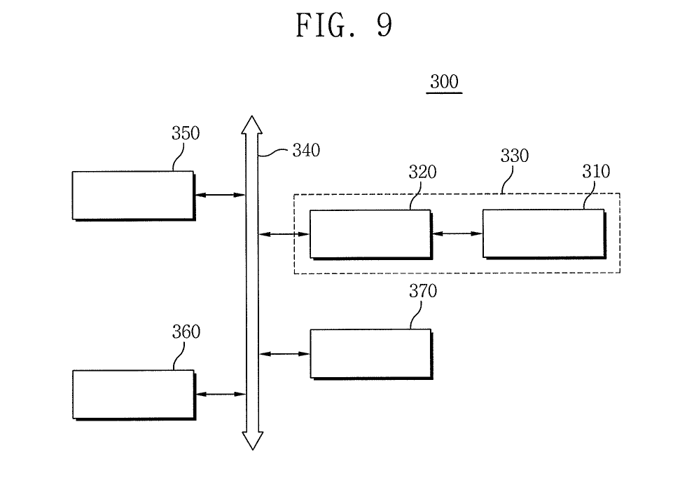

FIG. 9 is a block diagram of a memory system including a semiconductor device according to an embodiment of the inventive concept.

Referring to FIG. 9, a memory system 300 according to the inventive concept may include a semiconductor memory device 330, a central processing unit (CPU) 350, a user interface 360, and a power supply unit 370. The semiconductor memory device 330 may include a variable resistive memory device 310 and a memory controller 320. The CPU 350, the user interface 360, and the power supply unit 370 may be electrically connected to a system bus 340. Each of the variable resistive memory 310 and the memory controller 320 may include at least one semiconductor device 100 according to the embodiments of the inventive concept. Data received through the user interface 360 or processed by the CPU 350 may be stored in the variable resistive memory device 310 through the memory controller 320. The variable resistive memory device 310 may include a semiconductor disk drive, e.g., a solid state drive (SSD). In this case, wire speed of the memory system 300 may be markedly increased. Although not shown in FIG. 9, it will be apparent to those skilled in the art that the memory system 300 according to the inventive concept may further include an application chipset, a camera processor, e.g., a contact image sensor (CIS), or a mobile dynamic random access memory (mobile DRAM). Also, the memory system 300 may be applied to personal digital assistants (PDAs), portable computers, web tablets, wireless phones, mobile phones, digital music players, memory cards, or all devices capable of transmitting and/or receiving data in wireless environments.

The variable resistive memory device 310 or the memory system 300 according to the inventive concept may be mounted in packages having various shapes. For example, the variable resistive memory device 310 or the memory system 300 may be mounted in packages using various methods, such as a package on package (PoP) technique, a ball grid array (BGA) technique, a chip scale package (CSP) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat pack (MQFP) technique, a thin quad flatpack (TQFP) technique, a small outline (SOIC) technique, a shrink small outline package (S SOP) technique, a thin small outline (TSOP) technique, a thin quad flatpack (TQFP) technique, a system in package (SIP) technique, a multichip package (MCP) technique, a wafer-level fabricated package (WFP) technique, or a wafer-level processed stack package (WSP) technique.

According to the above-described inventive concept, the following effects can be expected.

First, since an a-Si region is formed using a dopant containing a Group IV or VIII element, the physical properties of a substrate may vary without changing the electrical properties of the substrate, thereby improving etching variation. For example, when a double-sigma-type strained semiconductor region is embedded, a sigma-type profile along which the variation of a tip may be improved in vertical and lateral directions may be formed, and the performance of a transistor may be enhanced with the improvement in the variation of the tip.

Second, a boundary of the a-Si region may function as an etch stop layer, thereby reducing etching variation. In particular, although the a-Si region may reduce etching variation in both lateral and vertical directions, a shallow a-Si region formed using a first ion implantation process may reduce etching variation chiefly in the lateral direction, while a thick a-Si region formed using a second ion implantation process may reduce etching variation chiefly in the vertical direction.

Third, a chemical dry etching process may be applied to an isotropic etching process, thereby increasing etch selectivity and etching uniformity. In this case, a combination of Cl₂ gas and an etch gas having a small number of F atoms may be used as a reactive gas. The isotropic dry etching process may be performed using, for example, an NF₃ reactive gas, without applying a bias voltage, thereby increasing etch selectivity by at least twice as much, and further enhancing etch uniformity.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A method of fabricating a semiconductor device, the method comprising:
forming a gate pattern on a substrate;
forming an amorphous silicon (a-Si) region adjacent to the gate pattern by implanting a dopant containing a Group IV or VIII element into portions of the semiconductor substrate;
forming gate spacers on sidewalls of the gate pattern;
forming a first cavity by etching the a-Si region and the substrate using a first etching process;
forming a second cavity by etching the substrate, such that the second cavity expands a profile of the first cavity in lateral and vertical directions; and
forming a strained semiconductor region in the second cavity.

2. The method as claimed in claim 1, wherein etching the a-Si region and the substrate includes performing a chemical dry etching process using a reactive gas containing nitrogen trifluoride (NF₃) and chloride (Cl₂).

3. The method as claimed in claim 1, wherein etching the a-Si region and the substrate is performed without applying a bias voltage.

4. The method as claimed in claim 1, wherein implanting the dopant includes implanting germanium (Ge) at a dose of about 4 E¹⁴/cm² or higher.

5. The method as claimed in claim 1, wherein implanting the dopant includes implanting silicon (Si) at a dose of about 1 E¹⁵/cm² or higher.

6. The method as claimed in claim 1, wherein forming the a-Si region includes forming a boundary of the a-Si region at a depth of about 100 Å to about 150 Å.

7. The method as claimed in claim 1, wherein forming the gate spacers is performed at a temperature of about 600 Å or lower.

8. The method as claimed in claim 1, wherein forming the strained semiconductor region includes filling the second cavity with a semiconductor material layer using a selective epitaxial growth (SEG) process, the semiconductor material layer including a SiGe layer or a Ge layer.

9. The method as claimed in claim 1, further comprising forming source and drain regions by implanting a dopant containing a Group III element into the strained semiconductor region, the source and drain regions having a junction deeper than a boundary of the strained semiconductor region.

10. The method as claimed in claim 1, wherein forming the a-Si region includes:
forming a first a-Si region in the substrate, such that the first a-Si region is vertically aligned with a sidewall of a first offset spacer on the gate pattern; and
forming a second a-Si region in the substrate, such that the second a-Si region is vertically aligned with a sidewall of a second offset spacer on the first offset spacer,
wherein etching the a-Si region includes performing an isotropic dry etching to etch the first and second a-Si regions, such that boundaries of the first and second a-Si regions are used as etch stop layers.

11. A method of fabricating a semiconductor device, the method comprising:
forming a gate pattern on a substrate;
forming first offset spacers on sidewalls of the gate pattern;
forming a first amorphous silicon (a-Si) region in the substrate, such that the first a-Si region is vertically aligned with a sidewall of one of the first offset spacers;
forming second offset spacers on the first offset spacers;
forming a second a-Si region in the substrate, such that the second a-Si region is vertically aligned with a sidewall of one of the second offset spacers;
forming gate spacers on the second offset spacers;
forming a first cavity having a longitudinal section with a reverse arch shape by etching the first and second a-Si regions; and
forming a second cavity having a longitudinal section with a double-sigma shape by etching the first cavity.

12. The method as claimed in claim 11, wherein forming the first and second a-Si regions includes implanting a dopant containing silicon (Si), germanium (Ge), argon (Ar), xenon (Xe), or krypton (Kr) into the substrate, such that the first and second a-Si regions have an etch selectivity of about 1.4 to about 2.4 with respect to the substrate.

13. The method as claimed in claim 12, wherein forming the first a-Si region includes forming a shallow pocket structure with a depth of about 100 Å to about 150 Å to control the width of the first cavity.

14. The method as claimed in claim 13, wherein forming the second a-Si region includes forming a thick pocket structure with a smaller width and greater depth than the first a-Si region to control the depth of the first cavity.

15. The method as claimed in claim 11, wherein etching the first and second a-Si regions includes performing an isotropic dry etching process using boundaries of the first and second a-Si regions as etch stop layers.

16. The method as claimed in claim 11, further comprising forming a strained semiconductor region in the second cavity, the strained semiconductor region including a SiGe layer or Ge layer having an amorphous or polycrystalline structure.

17. A method of fabricating a semiconductor device, the method comprising:
forming gate patterns on a crystalline semiconductor substrate;
forming an amorphous silicon (a-Si) region in the crystalline semiconductor substrate between adjacent gate patterns by implanting a dopant containing a Group IV or VIII element into the crystalline semiconductor substrate;
forming a first cavity by etching the a-Si region and portions of the crystalline semiconductor substrate using a dry isotropic etching process;
forming a second cavity by simultaneously expanding a profile of the first cavity in lateral and vertical directions; and
forming a strained semiconductor region in the second cavity.

18. The method as claimed in claim 17, wherein forming the a-Si region includes transforming a portion of the crystalline semiconductor substrate into an amorphous region by the implantation, such that only physical properties of the substrate are changed.

19. The method as claimed in claim 17, wherein forming the first cavity includes using a boundary between the a-Si region and the crystalline semiconductor substrate as an etch stop layer, such that a width of the first cavity equals a width of the a-Si region.

20. The method as claimed in claim 17, wherein the dry isotropic etching process is performed under no bias conditions and includes using a fluorine-based gas having a small number of fluorine atoms.
